(19) United States
(12) Patent Application Publication
(10) Pub. No.: US 2014/0354512 A1
(43) Pub. Date: Dec. 4, 2014

(54) TUNABLE FILTER DEVICE

(71) Applicant: Murata Manufacturing Co., Ltd., Nagaokakyo-shi (JP)

(72) Inventor: Michio KADOTA, Nagaokakyo-shi (JP)

(21) Appl. No.: 14/459,348

(22) Filed: Aug. 14, 2014

Related U.S. Application Data
(63) Continuation of application No. PCT/JP2013/052887, filed on Feb. 7, 2013.

(30) Foreign Application Priority Data
Feb. 20, 2012 (JP) 2012-034308

(51) Int. Cl. H03H 7/01; H01Q 1/50

(52) U.S. Cl. CPC H03H 7/17; H01Q 1/50; H03H 7/0161
USPC 343/904; 327/557

(57) ABSTRACT

A tunable filter device includes a first tunable filter with a first pass band, and a second tunable filter connected to the first tunable filter and having a second pass band located within the first pass band and a band width narrower than the band width of the first pass band. The second tunable filter includes a local oscillator that generates a predetermined frequency signal, a mixer that outputs a sum of and a difference between an output signal of the first tunable filter and the predetermined frequency signal output from the local oscillator, and an IF tunable filter connected to the mixer.

### BACKGROUND OF THE INVENTION

1. Field of the Invention

The present invention relates to a tunable filter device that is configured to change a pass band, and more specifically relates to a tunable filter device in which a center frequency and a bandwidth are capable of being changed.

2. Description of the Related Art

In recent years, mobile communication system apparatuses, such as cellular phones, have been required to support many communication standards. For example, frequency bands ranging from band 1 to band 25 are specified in a W-CDMA system cellular phone. Hence, a filter bank which includes many band pass filters supporting many bands is provided in a mobile communication system apparatus such as a cellular phone. It is necessary to switch filters in accordance with a frequency or band in use. This results in an increase in the number of components and a need for switch components for switching among filters and duplexers.

On the other hand, Japanese Unexamined Patent Application Publication No. 2009-130831 discloses a tunable filter that is capable of supporting a plurality of pass bands. FIG. 10 illustrates a circuit diagram of the tunable filter disclosed in Japanese Unexamined Patent Application Publication No. 2009-130831. A tunable filter 1001 includes an input terminal 1002 connected to an antenna terminal. A series arm resonator 1004 is connected between the input terminal 1002 and an output terminal 1003. A variable capacitor 1005 is connected in series with the series arm resonator 1004. A variable capacitor 1006 is connected in parallel with the series arm resonator 1004. On the other hand, a parallel arm resonator 1007 is connected between the output end of the series arm resonator 1004 and a ground potential. A variable capacitor 1008 is connected in parallel with the parallel arm resonator 1007. A variable capacitor 1009 is connected in series with the parallel arm resonator 1007.

The series arm resonator 1004, the variable capacitor 1005, and the variable capacitor 1006 form a series arm resonance unit 1010. Similarly, the parallel arm resonator 1007, the variable capacitor 1008, and the variable capacitor 1009 form a parallel arm resonance unit 1011.

In the tunable filter 1001, the frequencies and width of a pass band can be changed by changing the capacitances of the variable capacitor 1005, the variable capacitor 1006, the variable capacitor 1008, and the variable capacitor 1009.

According to the tunable filter 1001 disclosed in Japanese Unexamined Patent Application Publication No. 2009-130831, signals of a plurality of pass bands can be transmitted or received using a single filter device. However, in the tunable filter 1001, insertion loss in the pass bands is large. This is caused by the fact that the Q factors of the series variable capacitor 1005 and the parallel variable capacitor 1008 that considerably contribute to attenuation characteristics are low. On the other hand, the Q factor of a variable capacitor is not so high in the present state of affairs. Hence, with the tunable filter 1001, it is difficult to decrease the insertion loss, although a plurality of pass bands can be supported. Here, in the filter having a single-stage configuration such as the one illustrated in FIG. 10, steep attenuation characteristics on the two sides of a pass band are not obtained and, hence, a multi-stage resonator is usually formed. In this case, the numbers of the series variable capacitors 1005 and the parallel variable capacitors 1008, which cause degradation of the insertion loss characteristics, increase in proportion to the number of stages. Hence, the insertion loss characteristics of a filter are considerably degraded.

### SUMMARY OF THE INVENTION

Preferred embodiments of the present invention provide a tunable filter device that realizes low insertion loss, large out-of-band attenuation, and increased frequency selectivity.

A tunable filter device according to a preferred embodiment of the present invention includes an input terminal and an output terminal. The tunable filter includes a first tunable filter connected to the input terminal and a second tunable filter that is connected to the first tunable filter so as to receive an output signal of the first tunable filter. The second tunable filter is configured to output an output signal to the output terminal.

The second tunable filter preferably includes a local oscillator, a mixer, and an IF tunable filter. The local oscillator is configured to generate a predetermined frequency signal and to be capable of changing the predetermined frequency signal. The mixer is connected to the local oscillator and the first tunable filter and is configured to output a sum of and a difference between the frequency signal generated by the local oscillator and the output signal of the first tunable filter. The IF tunable filter is connected to the mixer so as to receive an output of the mixer and is configured to be capable of changing a band width while a center frequency is fixed.

A second pass band preferably is located within a first pass band and a band width of the second pass band is narrower than a band width of the first pass band, where the first pass band is a pass band of the first tunable filter and the second pass band is a pass band of the second tunable filter.

In a specific aspect of the tunable filter according to a preferred embodiment of the present invention, the IF tunable filter is a ladder filter including a series arm resonator and a parallel arm resonator. In this case, out-of-band attenuation is increased. Preferably, in the ladder filter, a series variable capacitor connected in series with the series arm resonator is not provided, and a parallel variable capacitor connected in parallel with the parallel arm resonator is not provided. In this case, the insertion loss is further decreased, and the out-of-band attenuation is further increased.

In still another specific aspect of the tunable filter according to a preferred embodiment of the present invention, the IF tunable filter preferably is a ladder filter including series arm resonators and parallel arm resonators, a series variable capacitor connected in series with each of the series arm resonators, and a parallel variable capacitor connected in parallel with each of the parallel arm resonators. The total number of the series variable capacitors and the parallel variable capacitors in the ladder filter is less than or equal to three. In this case, the insertion loss is further decreased, and the out-of-band attenuation is further increased.

In another specific aspect of the tunable filter according to a preferred embodiment of the present invention, a plurality of filter units each including a resonator and a series variable capacitor connected in series with the resonator are connected between an input end and an output end of the first tunable filter, and the number of the series variable capacitors in the first tunable filter preferably is less than or equal to three. Thus, the insertion loss is further decreased.

In still another specific aspect of the tunable filter device according to a preferred embodiment of the present invention, the tunable filter preferably is a reception filter connected to an antenna terminal of a cellular phone. Hence, a cellular phone supporting many communication standards is reduced in size.

In still another specific aspect of the tunable filter device according to a preferred embodiment of the present invention, the reception filter is a reception filter capable of receiving one of a plurality of pass bands within each communication band of a plurality of communication bands, the first tunable filter is configured to be capable of selecting at least two communication bands, and the second tunable filter is configured to be capable of selecting a pass band of any one band of the at least two communication bands.

In still another specific aspect of the tunable filter device according to a preferred embodiment of the present invention, the reception filter is a tunable filter, and the transmission filter is a fixed-band filter.

In a tunable filter device according to various preferred embodiments of the present invention, a first pass band is obtained by the first tunable filter, and a second pass band is selected by the second tunable filter within the first pass band. Hence, as the first tunable filter, a low-loss filter, although its out-of-band attenuation is not sufficient, preferably is used. As a result, loss is decreased. Further, the second tunable filter, which includes the above-described local oscillator, mixer, and IF tunable filter, ensures sufficient out-of-band attenuation in the second tunable filter, thus effectively enhancing selectivity. Hence, as a whole, a low-loss high-selectivity tunable filter device is provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a block diagram of a tunable filter device according to a first preferred embodiment of the present invention.

FIG. 2 is a circuit diagram of a first tunable filter of the tunable filter device according to the first preferred embodiment of the present invention.

FIG. 3 is a circuit diagram of an IF tunable filter used in a second tunable filter of the tunable filter device according to the first preferred embodiment of the present invention.

FIG. 4A to FIG. 4C are diagrams for describing the operation in the tunable filter device according to the first preferred embodiment of the present invention, wherein FIG. 4A is a diagram schematically illustrating attenuation frequency characteristics for describing the operation of the first tunable filter, FIG. 4B is a diagram schematically illustrating attenuation frequency characteristics for describing a frequency band selected by the second tunable filter, FIG. 4C is a diagram schematically illustrating attenuation frequency characteristics of the second tunable filter.

FIG. 5 is a diagram illustrating a change in attenuation frequency characteristics in the case where the series variable capacitance and the parallel variable capacitances are changed in the first tunable filter, in the first preferred embodiment of the present invention.

FIG. 6 is a diagram illustrating attenuation frequency characteristics of the IF tunable filter in the tunable filter device of the first preferred embodiment of the present invention.

FIG. 7 is a circuit diagram of an IF tunable filter in a tunable filter device according to a second preferred embodiment of the present invention.

FIG. 8 is a circuit diagram of an IF tunable filter in a tunable filter device according to a third preferred embodiment of the present invention.

FIG. 9 is a circuit diagram of an IF tunable filter in a tunable filter device according to a fourth preferred embodiment of the present invention.

FIG. 10 is a circuit diagram of an existing tunable filter.

### DETAILED DESCRIPTION OF THE PREFERRED EMBODIMENTS

Hereinafter, specific preferred embodiments of the present invention will be described with reference to the drawings so that the present invention will be clarified.

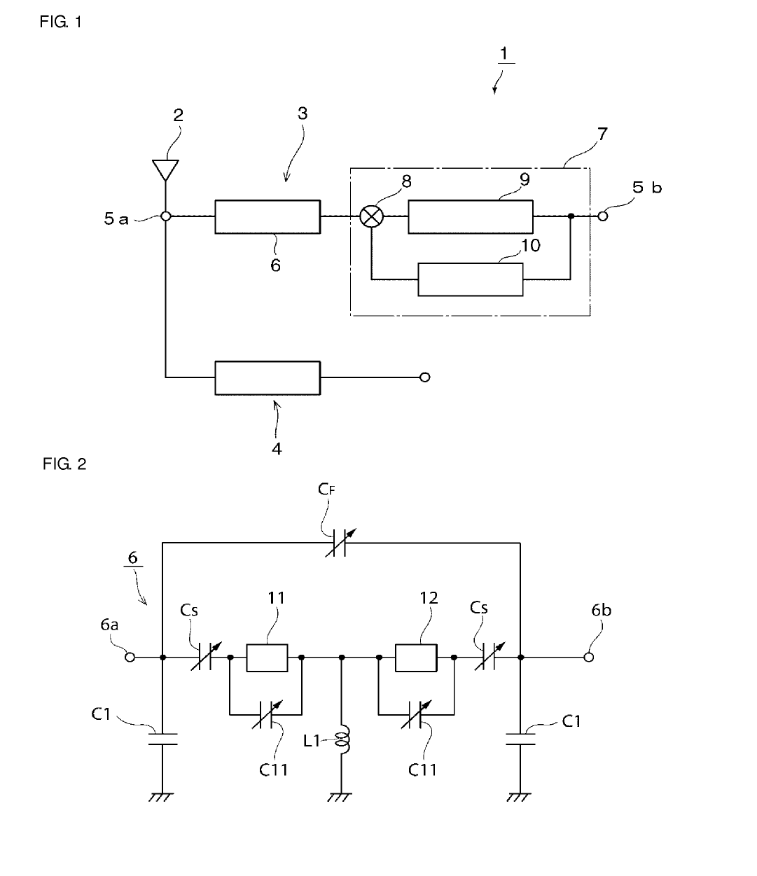

FIG. 1 is a block diagram illustrating a transmission/reception filter device which includes a tunable filter device according to a first preferred embodiment of the present invention. A transmission/reception filter device 1 includes an antenna 2. A tunable filter device 3 of the present preferred embodiment and a transmission filter 4 are connected to the antenna 2. The tunable filter device 3 of the present preferred embodiment defines a reception filter.

More specifically, the tunable filter device 3 includes an input terminal 5a connected to the antenna 2. The input terminal 5a is provided with a switch configured to switch between reception and transmission, and a first tunable filter 6 is connected to the switch. A second tunable filter 7 is connected to the output end of the first tunable filter 6. The output end of the second tunable filter 7 is connected to an output terminal 5b.

The second tunable filter 7 includes a mixer 8, an IF tunable filter 9, and a local oscillator 10. The input side of the mixer 8 is connected to the first tunable filter 6 and the local oscillator 10. In more detail, the mixer 8 mixes an output signal of the first tunable filter 6 and a predetermined frequency signal output by the local oscillator 10, thus outputting the sum of and difference between the two signals. The output side of the mixer 8 is connected to the IF tunable filter 9 so that the sum of and difference between the output signal of the first tunable filter 6 and the predetermined frequency signal generated by the local oscillator 10 are provided to the IF tunable filter 9. Here, in the IF tunable filter 9, either one of the sum of and difference between the output signal of the first tunable filter 6 and the predetermined frequency signal generated by the local oscillator 10, corresponding to the center frequency of the IF tunable filter 9, passes through the IF tunable filter 9 and is output to the output terminal 5b.

The local oscillator 10, which generates the predetermined frequency signal, is configured to be able to change the predetermined frequency signal.

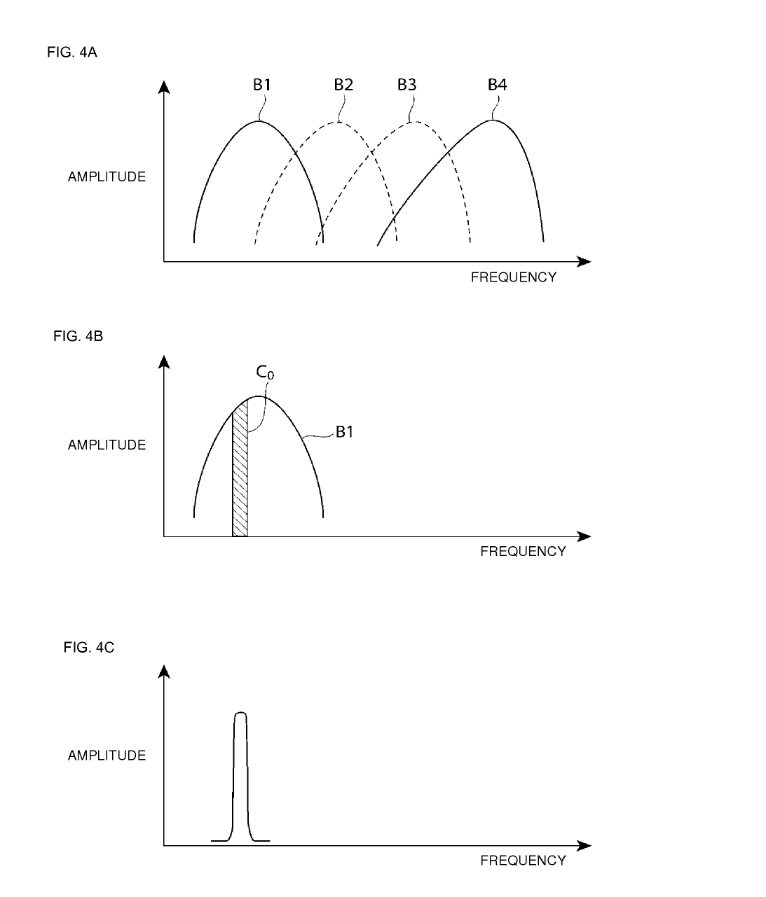

In the tunable filter device 3 of the present preferred embodiment, when it is assumed that the pass band of the first tunable filter 6 is a first pass band and the pass band of the second tunable filter 7 is a second pass band, the first pass band includes a plurality of communication bands that have the second pass band. Further, the band width of the second pass band is the pass band width of a single band among the plurality of communication bands within the first pass band. Here, the “communication bands” refer to the bands of, for example, Global System for Mobile Communications (GSM, trademark), Personal Communications Service (PCS), and Universal Mobile Telecommunications System (UMTS), for example. This will be described more specifically with reference to FIGS. 4A-4C.

FIG. 4A is a diagram schematically illustrating the attenuation frequency characteristics of the first tunable filter 6. In the first tunable filter 6, the pass band preferably is changed, as illustrated by a solid line B1, broken lines B2 and B3, and a solid line B4 in FIG. 4A. As a result, for example, a frequency region including the communication band of a cellular phone preferably is selected by the first tunable filter 6.

On the other hand, in a cellular phone that supports multiple bands, several communication bands having different frequency bands exist in the frequency band selected by the first tunable filter 6. It is necessary to receive a signal in a single band among the several communication bands.

Referring to FIG. 4C, the pass band of the second tunable filter 7 is configured such that a signal in a single band among the several bands described above is output.

In other words, the second pass band width is made to be a pass band width of a single band in the plurality of bands within the first pass band, such that a signal in a single pass band within the first pass band is output by the second tunable filter 7.

Note that the in the present preferred embodiment, the transmission filter 4 preferably is not a tunable filter and is a filter whose pass band is fixed. The transmission filter need not be a tunable filter. This is clear from the fact that, even when only a signal in a pass band in a certain single communication band is transmitted, since the reception filter is tunable, reception of the signal by adjusting the reception filter band to the certain single communication band is possible and, hence the function as a cellular phone is sufficiently realized.

In the tunable filter device 3 of the present preferred embodiment, when a signal in the second pass band described above is output, insertion loss is decreased and out-of-band attenuation is enhanced. This will be specifically described below.

FIG. 2 is a circuit diagram of the first tunable filter 6 of the present preferred embodiment. The tunable filter 6 includes an input terminal 6a and an output terminal 6b. The input terminal 6a is connected to the input terminal 5a described above. The output terminal 6b is connected to the mixer 8.

Resonators 11 and 12 are connected in series with each other between the input terminal 6a and the output terminal 6b. The resonator 11 preferably is a plate wave resonator in the present preferred embodiment. The resonator 12 similarly includes a plate wave resonator. However, the resonators 11 and 12 may include elastic wave resonators such as surface acoustic wave resonators, boundary acoustic wave resonators, and piezoelectric thin film resonators.

A series variable capacitor Cs is connected to the resonator 11. A variable capacitor C11 is connected in parallel with the resonator 11. Similarly, a series variable capacitor Cs and a variable capacitor C11 are connected to the resonator 12. A capacitor C1 is connected between the input terminal 6a and a ground potential. Similarly, another capacitor C1 is connected between the output terminal 6b and the ground potential. Further, a variable capacitor C_{F} is connected in parallel with a series arm, between the input terminal 6a and the output terminal 6b. The variable capacitor C_{F} may not be provided.

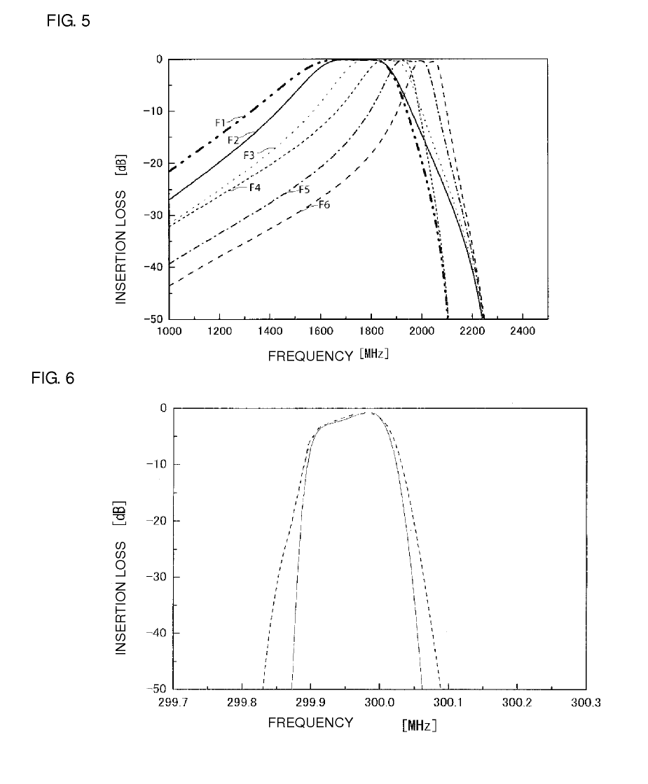

In the first tunable filter 6, a first pass band width preferably is changed by changing the series variable capacitances Cs and the variable capacitances C11. FIG. 5 is a diagram illustrating how the pass band changes in the tunable filter 6 of the present preferred embodiment in the case where the resonators 11 and 12 have the specifications described below, the capacitance C1 preferably is about 0.5 pF, an inductance L1 preferably is about 4.7 nH, and the series variable capacitances Cs and the variable capacitances C11 are changed as illustrated in Table 1, for example.

A transversal-wave-type plate wave resonator was constructed in which an aluminum IDT electrode with a wave length λ of about 2 μm and reflectors are formed on a LiNbO₃ thin plate with a thickness of about 200 nm and Euler angles (0°, 118°, 0°), for example. The number of pairs of electrode fingers of the IDT electrode is 40, and the number of electrode fingers of the reflector is 20, for example.

TABLE 1

| | Cs(pF) | C11(pF) |
|---|---|---|
| F1 | zero | 0.2 |
| F2 | zero | Zero |
| F3 | 2 | Zero |
| F4 | 1 | 0.2 |
| F5 | 0.6 | Zero |
| F6 | 0.4 | Zero |

As is clear from FIG. 5, it can be seen that the pass band considerably changes from F1 to F6, when the series variable capacitance Cs and the variable capacitance C11 are changed as illustrated in Table 1.

In this manner, in the first tunable filter 6, the pass band, i.e., the center frequency of the first pass band is considerably changed by changing the series variable capacitance Cs and the variable capacitance C11. In this case, the change in the pass band is realized by adjusting the series variable capacitance Cs and the variable capacitance C11. Note that it is possible to improve the skirt characteristics of the filter by connecting the variable capacitor C_{F} described above between the input terminal 6a and the output terminal 6b.

In general, when a resonator is arranged on a series arm connecting an input terminal to an output terminal, in a configuration in which a variable capacitor is connected in series with the resonator, the Q factor of the series variable capacitor considerably influences insertion loss. In other words, when the Q factor is low, the insertion loss is considerably increased. However, the Q factor of the series variable capacitor cannot be significantly increased.

In the present preferred embodiment, the number of series variable capacitors causing such an increase in insertion loss is made to be as small as two, for example. Hence, as illustrated in FIG. 5, an increase in the insertion loss is significantly reduced or prevented. For example, as is clear from FIG. 5, it can be seen that even when the first pass band is changed as described above, insertion loss in the pass band, i.e., the minimum insertion loss within the pass band is as comparatively small as about −2 dB to about −0.1 dB, for example. Hence, the first pass band is selected without considerably increasing the insertion loss, by using the first tunable filter 6.

However, as illustrated in FIG. 5, the first tunable filter 6 has relatively broad attenuation characteristics. Hence, the pass band C₀ described above cannot be selected with high accuracy.

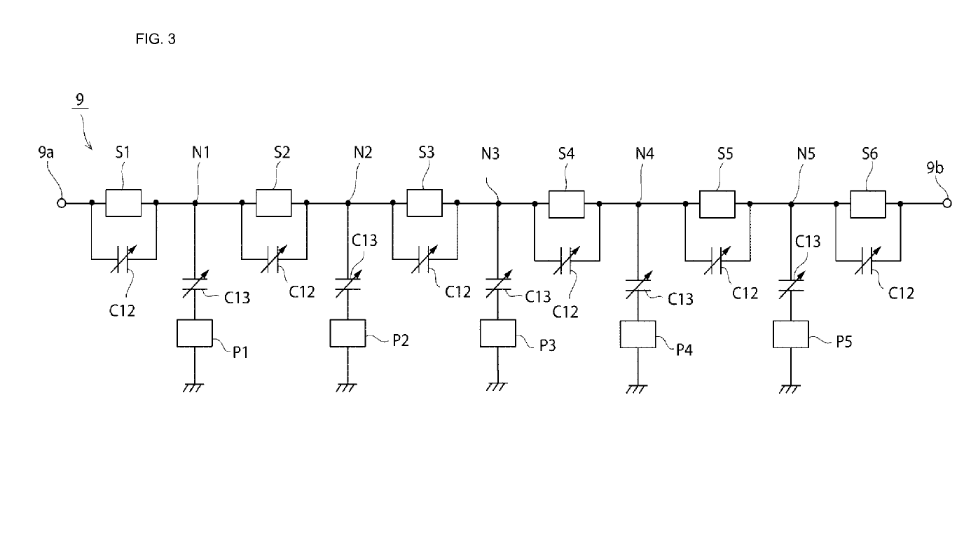

FIG. 3 is a circuit diagram of an IF tunable filter 9 used in the second tunable filter 7.

The IF tunable filter 9 includes an input terminal 9a and an output terminal 9b. The IF tunable filter 9 is a ladder filter including series arm resonators and parallel arm resonators. More specifically, series arm resonators S1 to S6 are connected in series with one another on the series arm. Variable capacitors C12 are respectively connected in parallel with the series arm resonators S1 to S6. However, variable capacitors are not connected in series with the series arm resonators S1 to S6. When variable capacitors are connected in series with the series arm resonators S1 to S6, insertion loss is increased, because the Q factors of the series variable capacitors are low.

On the other hand, a parallel arm resonator P1 is connected between the ground potential and a connection node N1 between the series arm resonators S1 and S2. A variable capacitor C13 is connected in series with the parallel arm resonator P1. Similarly, a parallel arm resonator P2 is connected between the ground potential and a connection node N2 between the series arm resonators S2 and S3. A variable capacitor C13 is connected in series with the parallel arm resonator P2. Similarly, parallel arm resonators P3 to P5 and variable capacitors C13 are respectively connected between the ground potential and connection nodes N3, N4, and N5.

The respective variable capacitors C13 are connected to the parallel arm resonators P1 to P5, but variable capacitors are not connected in parallel with the parallel arm resonators P1 to P5. When variable capacitors are connected in parallel with the parallel arm resonators P1 to P5, the insertion loss is increased.

In the second tunable filter 7, variable capacitors are not connected in series with the series arm resonators S1 to S6 and variable capacitors are not connected in parallel with the parallel arm resonators P1 to P5, in the IF tunable filter 9, as described above. Hence, a decrease in insertion loss is effectively reduced or prevented.

FIG. 6 is a diagram illustrating the transmission characteristics of the IF tunable filter 9 of the present preferred embodiment. The resonators, both series arm resonators and parallel arm resonators preferably are surface acoustic wave resonators which have been configured such that an IDT electrode made of Al and having a wave length λ of about 15.66 μm and reflectors are provided on an ST cut Y crystal substrate, with 50 pairs of electrode fingers for an IDT electrode and 40 electrode fingers for a reflector. Referring to FIG. 6, a solid line illustrates the case in which capacitors are not added and a dotted line illustrates the case in which the capacitance of variable capacitors C13 is about 9 pF, and the capacitance of variable capacitors C12 is about 1.3 pF, for example. As is clear from FIG. 6, by adding capacitors, the pass band is changed and a signal is output with high selectivity.

Referring back to FIG. 1, in the second tunable filter 7, the output signal of the first tunable filter 6 and a predetermined frequency signal generated by the local oscillator 10 are provided to the mixer 8, and the sum of and difference between the two signals are output. In other words, when the frequency of the output signal of the first tunable filter 6 is denoted by f1, and the frequency of a predetermined frequency signal generated by the local oscillator 10 is denoted by f₀, f1+f₀ and f1−f₀ are provided to the IF tunable filter 9. The predetermined frequency signal generated in the local oscillator 10 is selected in such a manner that f1−f₀ becomes equal to the center frequency of a pass band for a signal to be output. In other words, frequency conversion is performed such that the center frequency of the IF tunable filter becomes the same as the center frequency of the pass band C₀. As a result, the center frequency of the second pass band illustrated in FIG. 4C becomes the same as the center frequency of the pass band C₀.

In this manner, in the IF tunable filter 9 illustrated in FIG. 3, it can be seen that the band width of the second pass band and the attenuation characteristics are adjusted by adjusting the variable capacitance C12 and the variable capacitance C13, for a signal with a frequency of f1−f₀ provided from the mixer 8. In other words, the width of the second pass band in FIG. 4C is adjusted by selecting the center frequency of the second pass band using the local oscillator 10 and by adjusting the variable capacitance C12 and the variable capacitance C13. In this manner, a desired pass band width in the second pass band, for example, a signal in the pass band C₀ is capable of being output with high selectivity.

Further, since the first tunable filter 6 is configured as described above, the insertion loss is not considerably increased, and also in the second tunable filter 7, since the IF tunable filter 9 is configured as described above, the insertion loss is not considerably increased. In addition, since the second tunable filter 7 preferably includes the local oscillator 10, the mixer 8, and the IF tunable filter 9, out-of-band attenuation for the second pass band is made to be sufficiently large.

As described above, in the first tunable filter 6 illustrated in FIG. 2, the series variable capacitors Cs considerably contribute to adjustment of the first pass band but causes an increase in insertion loss. However, in the present preferred embodiment, since the number of the series variable capacitors Cs is as small as two, an increase in insertion loss is effectively significantly reduced or prevented. Note that when the number of the series variable capacitors Cs preferably is less than or equal to three, an increase in insertion loss is sufficiently reduced or prevented similarly. Hence, in a band pass filter in which a plurality of resonators are connected between the input terminal and the output terminal, it is preferable that the number of variable capacitors connected in series with the series resonators be less than or equal to three.

In other words, a band pass filter including three series resonators and three series variable capacitors connected in series or a band pass filter including a coil and a variable capacitor may be used instead of the first tunable filter 6 illustrated in FIG. 2.

Further, in various preferred embodiments of the present invention, the first tunable filter 6 is not limited to the configuration described above in which a plurality of resonators are connected between input terminal and output terminal. A filter with other circuit configurations such as a ladder filter or a lattice filter may be used. In any case, in the first tunable filter 6, which is allowed to have broad attenuation characteristics, it is preferable that the number of variable capacitors having an unfavorable influence on insertion loss, such as series variable capacitors connected to a series arm resonator and parallel variable capacitors connected to a parallel arm resonator be less than or equal to three.

In other words, for example, in a ladder filter having a configuration in which series variable capacitors are connected to series arm resonators and parallel variable capacitors are connected to parallel arm resonators, it is preferable that the total number of the series variable capacitors and parallel variable capacitors be less than or equal to three.

Further, as illustrated in FIG. 3, in the present preferred embodiment, the IF tunable filter 9 does not include a variable capacitor connected in series with a series resonator or a variable capacitor connected in parallel with a parallel resonator, which causes an increase in insertion loss. Hence, it is possible to select the second pass band without causing a considerable increase in insertion loss.

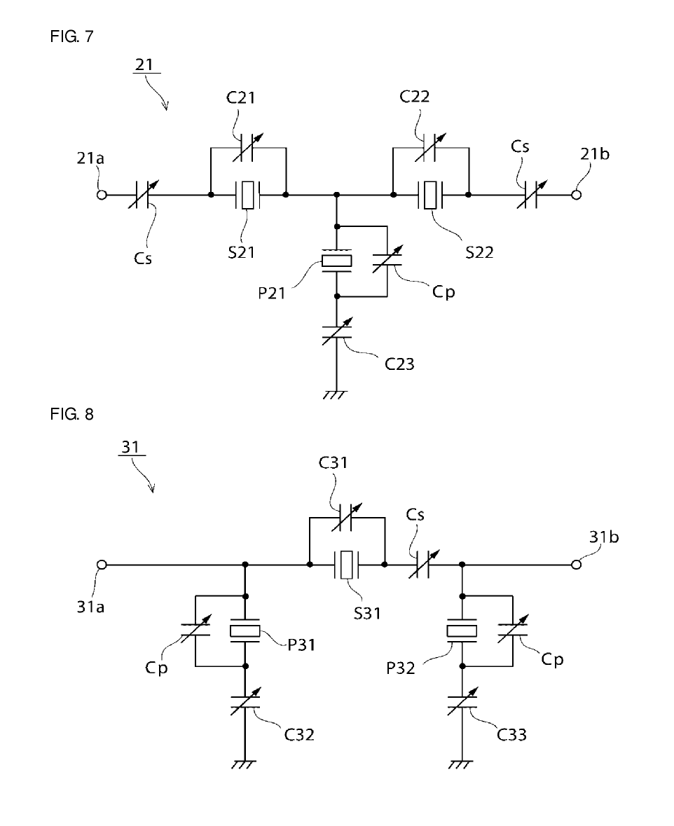

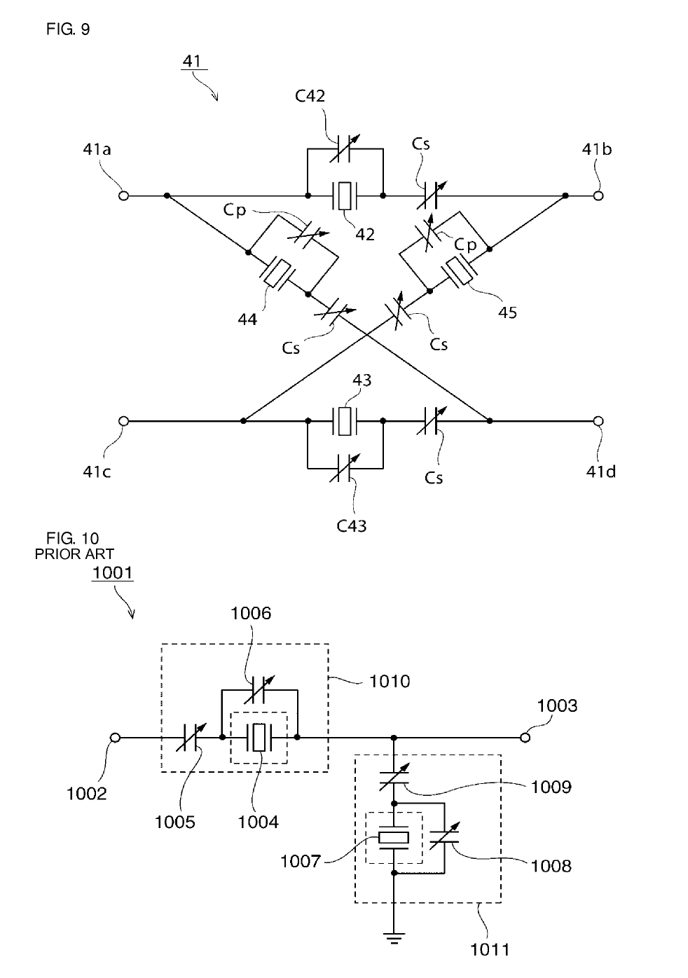

However, in various preferred embodiments of the present invention, the IF tunable filter 9 is not limited to the circuit illustrated in FIG. 3. FIG. 7 to FIG. 9 illustrate respective circuit configurations of IF tunable filters included in second to fourth preferred embodiments of the present invention. The second to fourth preferred embodiments preferably have the same configuration as the first preferred embodiment except for the circuit of the IF tunable filter.

In an IF tunable filter 21 illustrated in FIG. 7, series arm resonators S21 and S22 are connected between an input terminal 21a and an output terminal 21b. A parallel arm resonator P21 is connected between a ground potential and a connection node between a series arm resonator S21 and a series arm resonator S22. Hence, a ladder circuit including the two series arm resonators S21 and S22 and the single parallel arm resonator P21 is provided.

Here, a series variable capacitor Cs is connected in series with the series arm resonator S21. A variable capacitor C21 is connected in parallel with the series arm resonator S21. Similarly, a series variable capacitor Cs is connected in series with the series arm resonator S22 and a variable capacitor C22 is connected in parallel with the series arm resonator S22. A parallel variable capacitor Cp is connected in parallel with the parallel arm resonator P21 and a variable capacitor C23 is connected in series with the parallel arm resonator P21.

Also in the IF tunable filter 21, the total number of the series variable capacitors Cs and the parallel variable capacitor Cp having a significant influence on the insertion loss is made to be three as described above. Hence, similarly to the first preferred embodiment described above, an increase in insertion loss is significantly reduced or prevented and out-of-band attenuation is increased.

Referring to FIG. 8, in an IF tunable filter 31 included in the third preferred embodiment, a series arm resonator S31 is connected between an input terminal 31a and an output terminal 31b. A series variable capacitor Cs is connected in series with the series arm resonator S31 and a variable capacitor C31 is connected in parallel with the series arm resonator S31. A parallel arm resonator P31 is connected between the input terminal 31a and a ground potential. A parallel variable capacitor Cp is connected in parallel with the parallel arm resonator P31, and a variable capacitor C32 is connected in series with the parallel arm resonator P31. Similarly, a parallel arm resonator P32 is connected between the output terminal 31b and the ground potential. A parallel variable capacitor Cp is connected in parallel with the parallel arm resonator P32 and a variable capacitor C33 is connected in series with the parallel arm resonator P32.

Also in the IF tunable filter 31, the total number of the series variable capacitor Cs and the parallel variable capacitors Cp preferably is three. Hence, similarly to the first preferred embodiment, out-of-band attenuation is increased without causing a considerable increase in insertion loss.

An IF tunable filter 41 illustrated in FIG. 9 preferably has a lattice-type circuit configuration including input terminals 41a and 41c, and output terminals 41b and 41d. Here, a resonator 42 is connected between the input terminal 41a and the output terminal 41b, and a resonator 43 is connected between the input terminal 41c and the output terminal 41d. Respective series variable capacitors Cs are connected in series with the resonators 42 and 43, and variable capacitors C42 and C43 are respectively connected in parallel with the resonators 42 and 43. To realize lattice circuit configuration, a resonator 44 is provided on a line connecting the input terminal 41a and the output terminal 41d, and a resonator 45 is provided on a line connecting the input terminal 41c and the output terminal 41b. Respective series variable capacitors Cs are connected in series with the resonators 44 and 45, and respective parallel variable capacitors Cp are connected in parallel with the resonators 44 and 45. The lattice IF tunable filter 41 described above may be used.

Also in this case, out-of-band attenuation is increased without causing an increase in insertion loss, by making the total number of the series variable capacitors Cs and the total number of the parallel variable capacitors Cp be small.

Note that the resonators in the IF tunable filter 9 used in the second tunable filter 7 may be configured using not only surface acoustic wave resonators but also other piezoelectric resonators, such as boundary acoustic wave resonators, plate wave resonators, and piezoelectric thin film resonators. Further, although a tunable filter is used on the reception side in the present preferred embodiment, a configuration may be adopted in which the tunable filter is used on the transmission side.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A tunable filter device comprising:
an input terminal and an output terminal;
a first tunable filter connected to the input terminal; and
a second tunable filter that is connected to the first tunable filter to receive an output signal of the first tunable filter and that is configured to output an output signal to the output terminal; wherein
the second tunable filter includes:
a local oscillator configured to generate a predetermined frequency signal and to change the predetermined frequency signal;
a mixer that is connected to the local oscillator and the first tunable filter and that is configured to output a sum of and a difference between the frequency signal generated by the local oscillator and the output signal of the first tunable filter; and
an IF tunable filter that is connected to the mixer to receive an output of the mixer and that is configured to change a band width while a center frequency is fixed; wherein
a second pass band is located within a first pass band and a band width of the second pass band is narrower than a band width of the first pass band, the first pass band being a pass band of the first tunable filter and the second pass band being a pass band of the second tunable filter.

3. The tunable filter device according to claim 2, wherein the IF tunable filter is a ladder filter including a series arm resonator and a parallel arm resonator.

4. The tunable filter device according to claim 3, wherein in the ladder filter, a series variable capacitor connected in series with the series arm resonator is not provided, and a parallel variable capacitor connected in parallel with the parallel arm resonator is not provided.

5. The tunable filter device according to claim 2, wherein
the IF tunable filter is a ladder filter including series arm resonators and parallel arm resonators, a series variable capacitor connected in series with each of the series arm resonators, and a parallel variable capacitor connected in parallel with each of the parallel arm resonators; and
the total number of the series variable capacitors and the parallel variable capacitors in the ladder filter is less than or equal to three.

6. The tunable filter device according to claim 2, wherein
a plurality of filter units each including a resonator and a series variable capacitor connected in series with the resonator are connected between an input end and an output end of the first tunable filter; and
a number of the series variable capacitors in the first tunable filter is less than or equal to three.

7. The tunable filter device according to claim 2, wherein the first tunable filter is a reception filter connected to an antenna terminal of a cellular phone.

8. The tunable filter device according to claim 7, wherein
the reception filter is a reception filter configured to receive one of a plurality of pass bands within each communication band of a plurality of communication bands;
the first tunable filter is configured to be capable of selecting at least two communication bands; and
the second tunable filter is configured to be capable of selecting a pass band of any one band of the at least two communication bands.

9. The tunable filter device according to claim 8, wherein the reception filter is a tunable filter, and further comprising a transmission filter that is a fixed-band filter.

10. The tunable filter device according to claim 2, wherein the second pass band width a pass band width of a single band in the plurality of bands within the first pass band, such that a signal in a single pass band within the first pass band is output by the second tunable filter.

11. A transmission/reception filter device comprising:
a transmission filter defined by the tunable filter device according to claim 2;
a reception filter; and
an antenna; wherein
the reception filter and the transmission filter are connected to the antenna.

12. The transmission/reception filter device according to claim 11, wherein the reception filter is a fixed band filter.
